(19) United States
(12) Patent Application Publication
(10) Pub. No.: US 2026/0262362 A1
(43) Pub. Date: Sep. 3, 2026

(54) PHOTOVOLTAIC MODULE

(71) Applicant: DRACULA TECHNOLOGIES, VALENCE (FR)

(72) Inventors: Donia FREDJ, Marseille (FR); Sadok BEN DKHIL, VALENCE (FR); Brice CRUCHON, GUILHERAND GRANGES (FR)

(21) Appl. No.: 18/878,555

(22) PCT Filed: Sep. 19, 2023
(86) PCT No.: PCT/FR2023/051422

§ 371 Date: Dec. 23, 2024

(30) Foreign Application Priority Data
Sep. 19, 2022 (FR) 2209453
Mar. 21, 2023 (FR) 2302602

(51) Int. Cl. H10K 30/50; H10K 30/85; H10K 30/86; H10K 85/10

(52) U.S. Cl. CPC H10K 30/50; H10K 30/85; H10K 30/86; H10K 85/10; H10K 85/1135; H10K 85/141

(57) ABSTRACT

The invention concerns photovoltaic modules, and in particular photovoltaic modules comprising several Organic Photovoltaic Cells (OPC). A photovoltaic cell can include a transparent support, a lower electrode covering said support having an upper surface and a lower surface, a first interfacial layer having an upper surface and a lower surface, a photovoltaic active layer, and a second interfacial layer covering said photovoltaic active layer. The photovoltaic cell being characterized in that said first interfacial layer is an organic layer having a thickness of between 2 and 5 nm and comprising amine groups at its lower surface in contact with the upper surface of the lower electrode, and the first interfacial layer is continuous, transparent and free from metal oxide.

### CROSS-REFERENCE TO RELATED APPLICATIONS

The present application is a filing under 35 U.S.C. 371 as the National Stage of International Application No. PCT/FR2023/051422, filed Sep. 19, 2023, entitled “PHOTOVOLTAIC MODULE,” which claims priority to French Application No. 2209453 filed with the Intellectual Property Office of France on Sep. 19, 2022 and which also claims priority to French Application No. 2302602 filed with the Intellectual Property Office of France on Mar. 21, 2023, all of which are incorporated herein by reference in their entirety for all purposes.

### TECHNICAL DOMAIN OF THE INVENTION

The invention relates in general to photovoltaic cells and modules, and in particular to photovoltaic modules comprising several Organic Photovoltaic Cells (OPC).

For the purposes of this invention, an organic photovoltaic cell is a photovoltaic cell in which at least the photovoltaic active layer is made of an organic material.

### BACKGROUND OF THE INVENTION

Photovoltaic modules comprising organic photovoltaic cells represent a real interest in the photovoltaic domain. Indeed, the possibility of substituting inorganic semiconductors generally used in photovoltaic cells, such as silicon, copper, indium, gallium, selenium or cadmium telluride, increases the number of systems that can be produced and therefore the possibilities of use. The development of marketable photovoltaic modules comprising several organic photovoltaic cells is currently a major challenge.

In recent years, the development of organic photovoltaic cells has evolved through the use of the inkjet printing technique for their implementation (reference 1, reference 2). In 2014, the Applicant developed a process for manufacturing photovoltaic cells using this technique for printing part of the layers of these cells (reference 3).

Typically, an organic photovoltaic cell uses two electrodes, an upper electrode and a lower electrode, at least one of which is semi-transparent to light and the other is metallic and reflective. These electrodes are adapted to collect the photogenerated charges of the photovoltaic active layer. In order to block the leakage current and improve the extraction of these photogenerated charges, the frequently used approach consists in inserting interfacial layers between the photovoltaic active layer and each of the electrodes so as, among other things, to facilitate the movement of charges in the photovoltaic cell, the photogenerated charges being either electrons or holes (positive charges).

For example, the photovoltaic active layer can be composed of two organic materials, one an electron donor and the other an electron acceptor. For a photovoltaic active layer of an organic nature, P₃HT:PCBM is conventionally used (P₃HT being the acronym for poly(3-hexylthiophene) and PCBM being the acronym for [6,6]-phenyl-C₇₁-methylbutanoate).

As shown in FIG. 1, in a currently used conventional or normal-structured photovoltaic cell 1, a first interfacial layer 9, comprising for example a polymer blend of poly(3,4-ethylenedioxythiophene) and sodium poly(styrene sulfonate) (usually designated by the acronym PEDOT:PSS), is formed on a layer of indium tin oxide 3 (ITO), used as the lower electrode, which serves here as anode and is itself formed on a support. This indium tin oxide layer consists of a metal oxide which, in addition to conducting current, offers the property of being relatively transparent from 350 nm downwards. This is the material most commonly used to collect holes in organic photovoltaic cells. Above the first interfacial layer 9 is formed on a photovoltaic active layer 5 which may, for example, be based on P₃HT:PCBM, and above this photovoltaic active layer 5 is formed on a second interfacial layer 6 above which is formed on an opaque upper electrode 7 usually made of aluminum, or silver when this layer is formed by inkjet printing, and which serves here as cathode. The two electrodes used in the photovoltaic cell, i.e. the lower electrode and the upper electrode, must have specific properties to enable them to be integrated into organic photovoltaic cells. On the one hand, both electrodes must have high enough conductivities to allow maximum charge collection. On the other hand, the transparency of the lower electrode, i.e. generally the indium tin oxide layer, is also a fundamental characteristic for increasing the number of photogenerated charges in the photovoltaic active layer.

Inverted-structure photovoltaic cells are also available today. The major difference with the conventional structure is that the PEDOT:PSS interfacial layer is located between the photovoltaic active layer and the upper electrode, in this case the anode. In this configuration, the indium oxide layer, which is the lower electrode, acts as the cathode. It should be noted that inverted-structured photovoltaic cells have the advantage of better air stability than conventionally structured photovoltaic cells, and also generally higher conversion efficiencies.

For the purposes of this invention, the conversion efficiency of a photovoltaic cell is defined as the ratio between the maximum electrical power delivered by the cell and the incident light power, for a given spectral distribution and intensity.

It should be noted, moreover, that the above-mentioned high conversion efficiencies are ensured when photovoltaic modules of the current state of the art are exposed to external radiation, i.e. exposed to a light intensity greater than 2000 lux and in particular to radiation under standard AM1.5 conditions which corresponds to an exposure light intensity having a power of 100 mW/cm² which is equivalent to a light intensity approximately equal to 100,000 Lux. In particular, the high number of photogenerated charges requires the use of an anode with very high electrical conductivity to ensure good collection, in the photovoltaic active layer, of photogenerated charges so as, among other things, to minimize the accumulation phenomenon at the interfacial layers. This is why, in the case of an inverse structure, the upper electrode (or anode) is usually opaque and made of silver. In this case, conversion efficiencies can reach values between 15 and 17% for organic photovoltaic cells on laboratory-scale.

In reverse-structure photovoltaic cells currently in use, the first interfacial layer between the lower electrode and the photovoltaic active layer is a layer comprising nanoparticles based on metal oxides such as zinc oxide (ZnO), titanium oxides (TiOₓ), zinc oxides (AZO) or tin dioxide (SnO₂).

However, although this first interfacial layer offers many advantages and interesting electronic properties, it also has a number of drawbacks. Indeed, the availability of the oxides making up this layer, the cost of the raw materials, the process associated with its implementation and application to create the layer, the quantities of waste, in particular toxic waste, generated during its implementation, and the costly recycling means to be employed to treat this waste are all disadvantages to be noted.

This is why some manufacturers are looking to replace the first inorganic interfacial layer with an organic interfacial layer (organic polymers or molecules).

It should be noted, however, that the mobility of photogenerated charges in organic layers is generally very low (charge mobilities in semiconducting polymers are much lower than those observed in silicon (1000 cm²V⁻¹s⁻¹) and are generally lower than those measured in molecular semiconductors (around 1-15 cm²V⁻¹s⁻¹)), this has the effect of limiting their thickness to just a dozen nanometers, without which the transfer of photogenerated charges would not be possible. However, the deposition techniques used do not enable organic interfacial layers of such thicknesses and that are continuous and uniform to be deposited in a controlled manner.

As things stand, the production of photovoltaic cells comprising a first organic interfacial layer is not only costly, but also does not yet ensure the production of photovoltaic cells with optimum performance, or at least sufficient performance to ensure long-term use.

### SUMMARY OF THE INVENTION

The aim of the present invention is to remedy the above-mentioned drawbacks.

More precisely, the aim of the present invention is to propose a solution that enables the sustainable use of a photovoltaic cell whose manufacturing process is less costly than those of the prior art and comprises a first organic interfacial layer that can be deposited by inkjet printing on the first lower electrode. This first interfacial layer is uniform and has a low thickness (generally <5 nm). The low thickness of this first organic interfacial layer enables high light transparency and thus efficient passage of photons to reach the photovoltaic active layer, as well as a significant reduction in raw material costs.

To this end, the invention proposes a photovoltaic cell, comprising at least
a transparent support,
a lower electrode covering said support, said lower electrode comprising an upper surface and a lower surface,
a first interfacial layer, said first interfacial layer comprising an upper surface and a lower surface,
a photovoltaic active layer,
a second interfacial layer covering said photovoltaic active layer,
   the photovoltaic cell being characterized in that the first interfacial layer is an organic layer having a thickness of between 2 and 5 nm and comprising amine groups at its lower surface in contact with the upper surface of the lower electrode, and in that the first interfacial layer is continuous, transparent and free from metal oxide.

For the purposes of this invention, amine groups with a lower surface in contact with the upper surface of the lower electrode are understood to be a polar organic chemical compound derived from ammonia, resulting from the replacement of one or more hydrogens in the ammonia molecule by other substituents or radicals (alkyl or aryl). When one, two or three hydrogen atoms are substituted, amines are respectively primary, secondary and tertiary. Quaternary ammonium compounds can be found, those are ammonia derivatives consisting of a nitrogen atom substituted by 4 alkyl groups.

The photovoltaic cell according to the invention in particular overcomes the problem associated with the effect of prolonged exposure to light radiation in an indoor environment, manifested by the variation in solar cell output power that can be measured after illumination (commonly referred to as the “light soaking effect”), as the first interfacial layer is free of metal oxide, which is the main cause of this effect. In the absence of this effect, photovoltaic cells can be exposed in an indoor environment and operate under both solar and artificial radiation.

Indeed, this effect generally appears in the reverse-structure photovoltaic cells of the prior art, which incorporate a first interfacial layer comprising oxides, in particular zinc oxides. In particular, in an outdoor environment, this effect is reflected in the improved performance of photovoltaic cells under solar radiation over time. In particular, it has been observed that photovoltaic cells currently in use and subjected to an outdoor environment see their performance gradually increase over a certain period of time, before tending towards limit values. As a result, prolonged absence of exposure to UV light will generate a degradation in performance, and exposure to light will again be necessary to improve performance. However, in the context of an indoor environment where UV radiation is absent (LED-type lighting with visible light emission), the “light soaking effect” only generates a successive degradation of photovoltaic cell performance over time.

For the purposes of this invention, solar radiation means all the electromagnetic waves emitted by the sun, covering a wide band of wavelengths ranging from ultraviolet (approx. 200 to approx. 380 nm) to infrared (approx. 780 to approx. 10,000 nm), via the visible range (approx. 380 to approx. 780 nm).

For the purpose of this invention, artificial radiation means exposure to illumination defined by a light spectrum that covers little or no ultraviolet radiation. Artificial radiation generally comes from an LED-type light source with visible emission (wavelength between approx. 380 nm and approx. 780 nm).

For the purposes of the present invention, a transparent support or layer is a support or layer defined by a transparency coefficient greater than or equal to 80%, preferably greater than or equal to 85%, when exposed to radiation covering a light spectrum extending between 380 nm and 780 nm.

For example, the transparent substrate can be made of glass or a polymeric material, preferably one chosen from polyethylene terephthalate (commonly known by the acronym PET), polyethylene naphthalate (commonly known by the acronym PEN) or glass.

For example, the lower electrode can be a layer of indium tin oxide, a layer based on silver nanowires, a composite layer consisting of a silver grid and high-conductivity PEDOT:PSS, a layer of reduced graphene oxide or a layer of carbon nanotubes.

Note that the first interfacial layer is an electron transport layer and is located between the lower electrode and the photovoltaic active layer.

The photovoltaic active layer can be based on a “donor” material composed of a p-type semiconducting polymer and an “acceptor” material which can be a fullerene derivative or a n-type non-fullerene derivative. For example, the photovoltaic active layer may comprise a polymer blend comprising methyl [6,6]-phenyl-C₇₁-butanoate combined with poly(thienol[3,4-b]-thiophene or PBDB-T-2F (donor):IO4CI (acceptor), PffBT4T-2OD (donor):EH-IDTBR (acceptor), D18 (donor): Y6 (acceptor), PBDB-T-2F:Poly[(2,6-(4,8-bis(5-(2-ethylhexyl-3-fluoro)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5′-c′]dithiophene-4,8-dione)], IO4CI:3,9-bis[5,6-dichloro-1H-indene-1,3(2H)dione]-5,5,11,11-tetrakis(4-hexylphenyl)-dithieno[2,3-d:2′,3′-d′]-s-indaceno[1,2-b:5,6-b′]dithiophene, PffBT4T-2OD:Poly[(5,6-difluoro-2,1,3-benzothiadiazol-4,7-diyl)-alt-(3,3′″-di(2-octyldodecyl)-2,2′,5′,2″,5″,2′″-quaterthiophen-5,5′″-diyl)], EH-IDTBR: C₇₂H₈₈N₆O₂S₈

It should be noted that the second interfacial layer is a hole-transport layer and, in a first case, can be located between the photovoltaic active layer and an upper electrode. In a second case, the second interfacial layer may be the upper electrode, in which case it acts as an interface between the photovoltaic active layer and the environment outside the photovoltaic cell.

For example, the second interfacial layer may be a PEDOT:PSS layer.

It should be noted that the first interfacial layer is an organic layer with a thickness of between 2 and 5 nm, so as not to interfere with the absorption of photons into the photovoltaic active layer from external light radiation, and to avoid high resistance (polymers and small organic molecules have low charge mobility, so thick layers have high resistivities). Indeed, the photogenerated charges in the photovoltaic active layer have to pass through the first interfacial layer longitudinally before reaching the electrode, so the thicker the first interfacial layer, the longer the distance the charges have to travel, and the greater the chance of losing these charges through recombination phenomenon.

For the purposes of this invention, the lower surface of the first interfacial layer refers to the surface in contact with the upper surface of the lower electrode.

For the purposes of this invention, a metal oxide-free first interfacial layer is defined as a layer that does not contain any metal oxide, such as zinc oxide (ZnO), titanium oxides (TiOₓ), zinc oxides (AZO) or tin dioxide (SnO₂).

Furthermore, by way of example only, as a first interfacial layer, we can mention a layer comprising, as a substitute for the metal oxides currently used, a material selected from Poly(9,9-bis(3′-(N,N-dimethyl)-N-ethylammonium-propyl-2,7-fluorene)-alt-2,7-(9,9-dioctylfluorene))dibromide (PFN-Br), polyethyleneimine (PEI), PEIE, Poly [(9,9-bis(3′-(N,N-dimethylamino)propyl)-2,7-fluorene)-alt-2,7-(9,9-dioctylfluorene)](PFN), N,N′-Bis(N,N-dimethylpropan-1-amine oxide)perylene-3,4,9,10-tetracarboxylic diimide (PDI-NO) or N,N′-Bis{3-[3-(Dimethylamino)propylamino]propyl}perylene-3,4,9,10-tetracarboxylic diimide (PDINN).

Advantageously, it is preferable to optimize the interfaces between the first interfacial layer and adjacent layers to ensure efficient transfer of the photogenerated charges. Consequently, the first interfacial layer can have an Rms roughness of less than 5 nm, preferably between 2 nm and 5 nm.

Advantageously, the first interfacial layer may comprise nitrogen.

Advantageously, the second interfacial layer may comprise a polymer blend of poly(3,4-ethylenedioxythiophene) and sodium poly(styrene sulfonate).

In a first variant of a particular embodiment, the photovoltaic cell may further comprise a upper electrode covering the second interfacial layer.

By way of example, this upper electrode can be a reflective metal electrode, for example made of silver.

In a second variant of a particular embodiment, the second interfacial layer comprising the polymer blend of poly(3,4-ethylenedioxythiophene) and sodium poly(styrene sulfonate) can be an upper electrode.

According to this second variant of a particular embodiment, the second interfacial layer can preferably be continuous, and can have a fibrous structure and an average thickness of between 100 nm and 400 nm. Under these conditions, the second interfacial layer can have an electrical resistivity of between 50 and 150 ohm/sq.

For the purposes of this invention, a continuous layer is one that contains no holes (the entire surface of the layer is covered by the interfacial layer material).

For the purpose of this invention, a fibrous structure means a particular structuring of the layer on a nanometric scale by forming PEDOT:PSS fibers. The conductive PEDOT:PSS fibers are well percolated between them, ensuring continuity of the material and consequently facilitating charge transport in the layer: there will be less resistance to charge transport in the layer and therefore improved layer conductivity.

According to this second variant, a significant service life of the photovoltaic cell is ensured under artificial radiation. This second variant also has the advantage of ensuring the operation of organic photovoltaic cells under artificial radiation by dispensing with the need to be exposed to solar radiation, in particular the need to be exposed to ultraviolet irradiation.

According to one or other of the two variants of an embodiment described above, the photovoltaic cell can be completely organic.

For the purpose of this invention, a completely organic, photovoltaic cell is a photovoltaic cell in which each of its constituent layers is organic in nature, with the exception of the substrate. In addition to carbon, which is the essential component of an organic material, it may also contain the hydrogen (H), oxygen (O), nitrogen (N), phosphorus (P), sulfur (S) and iron (Fe) elements.

Advantageously, the photovoltaic cell comprises a first interfacial layer obtained by digital inkjet printing on the lower electrode of an organic ink composition having a viscosity of between 2 and 50 mPa·s at 20° C. and comprising:
between 0.1% and 0.5% by weight of at least one organic polymer or organic molecule, based on the total weight of said ink composition, the organic polymer or organic molecule comprising amine groups and being soluble in polar solvents,
between 2% and 10% by weight of additives, based on the total weight of said ink composition,
between 80% and 90% by weight of one or more polar solvents, based on the total weight of said ink composition, and
between 1% and 5% by weight of water, based on the total weight of said ink composition.

The invention also offers a photovoltaic module comprising at least two photovoltaic cells according to either one of the two variants of a previously described embodiment, a first photovoltaic cell and a second photovoltaic cell, the upper electrode of the first photovoltaic cell being in contact with the lower electrode of the second photovoltaic cell.

The photovoltaic module according to the invention has the advantage of performing well when exposed to light levels of between 5,000 and 10,000 lux. This enables it to operate in mixed lighting conditions, i.e. under solar or artificial radiation.

The photovoltaic module according to the invention has high stability under accelerated aging in artificial light.

The photovoltaic module according to the invention exhibits high stability under accelerated aging in artificial light emitted by LEDs, due to the fact that the first interfacial layer used according to the invention is organic and therefore has no sensitivity to UV radiation (no “light soaking” effect). The absence of UV does not hinder the operation of such a first interfacial layer, unlike interfacial layers based on metal oxides (commonly used in OPV), which require UV activation to render the layers functional. Indeed, the absence of UV generally leads to significant drops in performance over time for metal oxide-based interfacial layers.

The invention also proposes a composition of an organic ink, capable of being formed by digital inkjet printing to a lower electrode of a photovoltaic cell described above, to form a first interfacial layer, the organic ink having a viscosity between 2 and 50 mPa·s at 20° C. and comprising:
between 0.1% and 0.5% by weight of at least one organic polymer or organic molecule relative to the total weight of the ink composition, the organic polymer or organic molecule comprising amine groups and being soluble in polar solvents,
between 2% and 10% by weight of additives relative to the total weight of the ink composition,
between 80% and 90% by weight of one or more polar solvents relative to the total weight of the ink composition, and
between 1% and 5% by weight of water, based on the total weight of the ink composition.

Advantageously, the organic ink has a viscosity of between 2 and 50 mPa·s at 20° C., and preferably between 2 and 20 mPa·s, and even more preferably between 7 and 12 mPa·s.

It should be noted that such a composition is significantly more stable than the metal oxide nanoparticle-based inks generally used in the prior art to form the interfacial layers of photovoltaic cells.

In particular, the ink according to the invention also has the advantage of not generating any aggregation or phase separation for a few hours, or even a few days (at least two hours), which ensures a stable printing phase without nozzle loss. In addition, this ink composition allows a nozzle opening time of more than 5 minutes, or even 10 minutes, thus avoiding rapid nozzle clogging during the inkjet printing phase.

In addition, this composition has the advantage of low cost, as organic polymers and organic molecules are less expensive than metal oxides, and their use concentration is lower than the latter.

In addition, this composition makes it possible to print, by digital inkjet printing, complete and uniform layers having roughnesses <2 nm and having well-defined edges with thicknesses between 2 nm and 5 nm, and to avoid the problems associated with the use of metal oxides, in particular the problems that can arise from the effect of prolonged exposure to light radiation. This stable composition is formulated to be formed by digital inkjet printing using conventional non-toxic solvents, enabling the composition to be deposited in ambient air.

In particular, organic polymers and organic molecules have the advantage of not being sensitive to ultraviolet radiation, this being linked to their intrinsic characteristics which are different from those of metal oxide nanoparticles.

Indeed, a conventional organic photovoltaic cell containing a metal oxide electron transport layer (e.g. zinc oxide or titanium oxide) generally needs to be exposed to UV light to form an ohmic contact between the metal oxide and the other layers (photovoltaic active layer and electrode). The nature of the bond between the organic intermediate layer and the lower electrode (ITO) facilitates the formation of an ohmic contact without exposure to UV light, thus reducing damage to the organic photovoltaic cell resulting from such exposure.

Additives can be used here to solubilize the organic polymer or organic molecule, and have high evaporation temperatures to prevent nozzle clogging and improve ink viscosity. The materials generally used for inorganic interfacial layers (such as metal oxides) are soluble in particular solvents, which are generally highly volatile alcohols that are undesirable for inkjet printing. Organic materials such as polymers or molecules can be soluble in a wide variety of solvents, so there's more choice when it comes to avoiding nozzle clogging and improving ink viscosity. Examples of additives include ethylene glycol, diethylene glycol and glycerol.

Advantageously, the organic polymer or organic molecule can comprise a nitrogen-containing compound, preferably an amine compound and more preferably a primary amine group, a secondary amine group, or a tertiary amine group. The amine compound may further comprise an acyclic group (the nitrogen atom is bonded to one or more alkyl groups), an Alicyclic group (the nitrogen atom is bonded to a non-aromatic ring), an Aromatic group (the nitrogen atom is bonded to an aromatic ring) and/or a Heterocyclic group (the nitrogen atom is engaged in a ring which may or may not be aromatic).

Advantageously, non-toxic solvents such as alcohols or water are good solvents for the polymer or organic molecule. Consequently, said one or more solvents may be selected from ethanol, isopropanol, hexanol, terpiniol, ethylene glycol, deionized water, phosphate saline buffer solution, butanol, di-ethylene glycol, glycerol.

Advantageously, the intermediate layer comprises an electron-donating compound, preferably a nitrogen-containing compound, a phosphorus-containing compound and/or a sulfur-containing compound.

Advantageously, the organic polymer or organic molecule can be selected from Poly(9,9-bis(3′-(N,N-dimethyl)-N-ethylammonium-propyl-2,7-fluorene)-alt-2,7-(9,9-dioctylfluorene))dibromide (PFN-Br), polyethyleneimine (PEI), PEIE, Poly [(9,9-bis(3′-(N,N-dimethylamino)propyl)-2,7-fluorene)-alt-2,7-(9,9-dioctylfluorene)] (PFN), N,N′-Bis(N,N-dimethylpropan-1-amine oxide)perylene-3,4,9,10-tetracarboxylic diimide (PDI-NO) or N,N′-Bis{3-[3-(Dimethylamino)propylamino]propyl}perylene-3,4,9,10-tetracarboxylic diimide (PDINN).

The invention has the advantage of overcoming a problem associated with the use of the lower electrode (preferably based on ITO, which is a material with a work output equal to 4.7 eV), which constitutes a barrier to the flow of charges from the photovoltaic active layer to the layer of the lower electrode. The first organic layer free from metal oxide reduces the energy barrier between the photovoltaic active layer and the layer of the lower electrode by lowering the work output of the latter. Rather than a Schottky contact, the final result is an ohmic contact that favors charge collection, particularly electron collection. In particular, according to the invention, adsorption of the first organic layer free from metal oxide, due to the transfer of charges, in particular protons, from the hydroxyl groups to the amine groups, generates a dipole opposite to [symbol] ( [symbol] being a surface dipole), leading to a reduction of [symbol] which reduces the work output of the lower electrode.

Advantageously, the thickness of the second layer of the lower electrode can be between 2 and 5 nm and can include amine groups on its lower surface in contact with the upper surface of the first layer of the lower electrode.

Advantageously, the organic polymer or organic molecule may comprise nitrogen.

The invention further proposes a method of manufacturing a photovoltaic cell, comprising the following steps:
a) providing a support;
b) forming a lower electrode on said support;
c) forming on said lower electrode a first organic interfacial layer comprising a lower surface including amine groups in contact with the lower electrode, the first interfacial layer having a thickness of between 2 and 5 nm, being continuous, transparent, free from metal oxide and obtainable after digital inkjet printing of the ink composition mentioned above;
d) forming of a photovoltaic active layer on said first interfacial layer;
e) forming a second interfacial layer on said photovoltaic active layer;
   said process being characterized in that steps b), c), d) and e) are each carried out by depositing ink compositions by digital inkjet printing, followed by thermal treatment, said ink composition used in step c) comprising a mixture based on organic molecules soluble in polar solvents.

Advantageously, the invention makes it possible to manufacture a photovoltaic cell comprising a first interfacial layer from an ink composition by digital inkjet printing. This composition is preferably based on non-toxic solvents known to the skilled person and on organic materials free from metal oxide, so as to enable them to be deposited in ambient air by digital inkjet printing. As a result, step c) of forming the first organic interfacial layer is easy to implement, as it eliminates the need to use metal oxide-based interfacial layers, which require special precautions when used in a standard environment (ambient air).

Advantageously, it is preferable not to alter the support and layers previously formed in step c). Consequently, the thermal treatment in step c) can be an annealing treatment carried out at a temperature of between 70° C. and 130° C., for a duration of between 1 and 5 minutes.

Advantageously, the wettability of the composition from which the first organic interfacial layer is derived can preferably be compatible with flexible substrates in polyethylene terephthalate, for example, to facilitate the formation of a continuous film with well-defined edges by digital inkjet printing.

Further advantages and features of the present invention will become apparent from the following description, made with reference to the appended figures and the following examples:

### BRIEF DESCRIPTION OF FIGURES

FIG. 1 shows a schematic cross-sectional view of a photovoltaic cell with a conventional structure; and

FIG. 2 shows a schematic cross-sectional view of a photovoltaic module 10 comprising photovoltaic cells 21 and 22 in a particular embodiment of the invention.

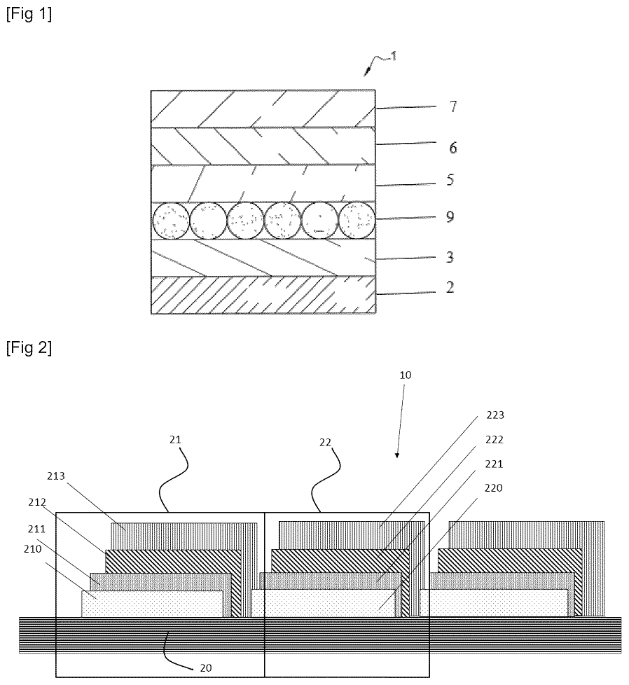

FIG. 1 is described in the foregoing overview of the prior art, while FIG. 2 is described in greater detail in the following examples, which illustrate the invention without limiting its scope.

### EXAMPLES

### Products

support 20 in PET or glass;
cleaning solvents:
   in the case of rigid glass supports: deionized water, Acetone, Ethanol, Isopropanol, and
   in the case of flexible substrates, as these are protected by plastic films, they do not require cleaning as in the case of rigid substrates;

A first ITO-based lower electrode 210 already deposited on the support 20 of the photovoltaic cell 21 and a first ITO-based lower electrode 220 already deposited on the support 20 of the photovoltaic cell 22 marketed by Addev Materials Micel (France).

A first ink composition E11 for making a first organic interfacial layer 211 comprising a lower surface including amine groups in contact with the discontinuous lower electrode (ITO) so that the lower electrode is partially covered by the first interfacial layer 221 of the photovoltaic cells 21 and 22 of the photovoltaic module of FIG. 2
Ink E11 comprises:
a first solvent 1: Butanol at a mass concentration approximately equal to 91.094% relative to the total weight of ink E11,
a second solvent 2: deionized water at a concentration by weight of approximately 3.124% relative to the total weight of ink E11,
an additive: ethylene glycol at a concentration by weight of approximately 5.563% based on the total weight of E11 ink,
a PEI at a concentration by weight of approximately 0.219% based on the total weight of E11 ink,
   The solvents, additives and PEI are marketed by Merck®.

A second ink composition E20 for making the photovoltaic active layers 212 and 222 of the photovoltaic cells 21 and 22 of the photovoltaic module of FIG. 2.
The ink E20 for making the photovoltaic active layers 212 of the photovoltaic cell 21 comprises:
E21 polymer blend of methyl [6,6]-phenyl-C₇₁-butanoate (marketed by Nano-C® under the trade name PC70BM) and poly(thienol[3,4-b]-thiophene (marketed by Raynergy Tek® under the trade name PV2000);
O-xylene as solvent (ortho-xylene of formula C₆H₄(CH₃)₂); and
Tetralin (1,2,3,4-tetrahydronaphthaline) as additive.
Ink E20 for making the photovoltaic active layers 222 of photovoltaic cell 22 comprises:
E22 polymer blend of methyl [6,6]-phenyl-C₇₁-butanoate (marketed by Nano-C® under the trade name PC70BM) and poly(thienol[3,4-b]-thiophene (marketed by 1-Materials under the trade name PTB7-Th);
O-xylene as solvent (ortho-xylene of formula C₆H₄(CH₃)₂); and
Tetralin (1,2,3,4-tetrahydronaphthalene) as additive.
   The PV2000 polymer of blend E21 or the PTB7-Th polymer of blend E22 are present in these second ink compositions at a level of 10 mg/ml.
   The weight ratio of PV2000 polymer from blend E21 or PTB7-Th polymer from blend E22 to PC70BM is 1:1.5.
   The volume ratio between O-xylene solvent and Tetralin additive is 97:3 in these second compositions.
   A second E20 ink composition is produced by adding the solvent and additive to the E21 or E22 polymer blend and maintaining this mixture for 24 hours with stirring on a hot plate at 80° C. at a speed of 700 RPM.

A second alternative E20 ink composition (E20-alt) for making the photovoltaic active layers 212 and 222 of the photovoltaic cells 21 and 22 of the photovoltaic module of FIG. 2.
The E20-alt ink comprises:
PC60BM: [60]PCBM, 3′H-cyclopropa[1,9][5,6]fullerene-C60-Ih-3′-butanoic acid 3′-phenyl methyl ester marketed by Special Carbon Products;
poly(thienol[3,4-b]-thiophene marketed by Raynergy Tek® under the trade name PV2000);
O-xylene as solvent (ortho-xylene of formula C₆H₄(CH₃)₂); and
Tetralin (1,2,3,4-tetrahydronaphthalene) as an additive.
   The PV2000 polymer is present in this second ink composition at 15 mg/ml.
   The weight ratio of PV2000 polymer to PC60BM polymer is 1:1.5.
   The volume ratio between O-xylene solvent and Tetralin additive is 50:50 in these two second compositions.
   The second E20-alt ink composition is kept for 24 hours under agitation on a hot plate at 80° C. at a speed of 700 RPM.

Third ink composition E30 for making the upper electrodes 213 and 223 (or anode) of the photovoltaic cells 21 and 22 of the photovoltaic module of FIG. 2.
Ink E30 comprises:
PEDOT:PSS marketed by Agfa® under the trade name IJ1005 or PEDOT:PSS marketed by Agfa® under the trade name ORGACON S315;
Triton X-100 (4-(1,1,3,3-tetramethylbutyl)phenyl-polyethylene glycol formula Oct-C₆H₄—(OCH₂CH₂)ₓOH, x=9-10) marketed by Merck® as detergent/surfactant;
Ethanediol (or ethylene glycol, formula HOCH₂CH₂OH) marketed by Merck®;
glycerol (1,2,3-Propanetriol or glycerin, formula HOCH₂CH(OH)CH₂OH) marketed by Merck®;
deionized water, produced in the laboratory or marketed by PURELAB® classic under the brand name ELGA® for water.

A third alternative E30 ink composition (E30-alt) for making the upper electrodes 213 and 223 (or anode) of the photovoltaic cells 21 and 22 of the photovoltaic module of FIG. 2.
The E30-alt ink comprises:
PEDOT:PSS marketed by Agfa® under the trade name IJ1005,
Triton X-100 (4-(1,1,3,3-tetramethylbutyl)phenyl-polyethylene glycol of formula Oct-C₆H₄—(OCH₂CH₂)ₓOH, x=9-10) marketed by Merck® as detergent/tensioactive.

### Tests

### Rms Roughness Measurement

These measurements are carried out using an atomic force microscope (Nanoscope III Multimode SPM from Brucker®, used in intermittent contact mode (or “tapping mode”), with hq:nsc15 tips marketed by MiKromasch® and having a curvature radius of 8 nm), the measurements were carried out on various samples of photovoltaic cells according to the invention and according to the prior art.

### Layer Thickness Measurement

The thickness of printed layers is measured using a DektakXT tip profilometer marketed by BRUKER, based on a scratch made with a cutter blade (thus creating a channel with the thickness of the deposit). This is a contact profilometer that measures variations in terrain by vertically moving a pointed stylus across the surface, applying a constant contact force and revealing any unevenness. The sample is placed on a plate which allows it to move at a given speed over a chosen distance. The thickness values presented in this patent application correspond to the average of five measurements taken at six different points on the same step of a sample. Before measurements are taken, the length of the zone scanned, its duration, the force with which the stylus is pressed and the measurement range must be defined.

### Electrical Resistivity Measurement

This measurement is carried out using the 4-tips technique, as follows:
the 4 tips are aligned far from the edges of the layer to be characterized;
these 4 tips are equidistant from each other; and
current is generated by a current generator between the outer tips, while voltage is measured between the inner tips. The ratio between the measured voltage and the current flowing through the sample gives the resistance of the section between the inner tips.

### Viscosity Measurement:

The viscosity of a fluid is reflected in its resistance to deformation or relative sliding of its layers. During the flow of a viscous fluid in a capillary tube, for example, the velocity of the molecules (v) is at its highest in the axis of the tube, decreasing until it reaches zero at the wall, while relative sliding occurs between the layers, giving rise to tangential frictional forces. In fluids, tangential forces depend on the nature of the fluid and its flow regime.

The Ubbelhode viscometer is placed in a thermostat maintained at a constant temperature (25° C. in our case). We measure the flow time of a constant volume V defined by two reference marks (M1 and M2) located on either side of a small reservoir surmounting the capillary.

### Photovoltaic Performance Measurement Indoors:

The study of module ageing under permanent lighting is carried out using an indoor characterization bench. The characterization bench comprises an opaque enclosure (to avoid any light coming from the outside) equipped with a LED lighting source (in particular a Keithley 2450 source-meter) and a computer with a LabVIEW program for automatic measurement of module performance (determination of photovoltaic parameters) at a well-defined frequency (e.g. 10 times a day). The photovoltaic modules are permanently illuminated by a lighting source with a light intensity of around 1000 lux measured by a luxmeter (in particular the Chauvin Arnoux Ca 1110 luxmeter) compatible with a wide variety of light sources, including LED and fluorescent light up to 200,000 lux, in compliance with class C of standard NF C 42-710.

The lighting source used for indoor and performance measurements is a Philips LED Panel 60×60 cm²-4385K with an emission spectrum in the visible range.

### Morphology Characterization:

AFM (Atomic Force Microscope) measurements to reproduce surface topography and TEM (Transmission Electron Microscopy) to validate the crystalline nature of the materials and the size of nanoparticles present in the layers.

### Filling Factor

The fill factor is the ratio between maximum electrical power and the product of short-circuit current and open-circuit voltage. It is generally expressed as a percentage.

EXAMPLE 1: Obtaining an example of an E11 ink composition for forming the first organic interfacial layer 211 on the layer of the lower electrode 210.

PEI is used to obtain the E11 ink composition, the composition of which is detailed below:

The E11 ink formulation is prepared in two steps:

### Step 1: Preparation of the Stock Solution:

Weigh 0.35 g PEI (interlayer polymer)
Add 5 ml of ionized water to these 0.35 g of PEI
Stir at 60° C. for at least 4 h to obtain the stock solution.

### Step 2: Preparation of E11 Ink Formulation:

Take 250 μL of the stock solution,
Add 9 ml Butanol,
Add 400 μL ethylene glycol,
   Stir the mixture at room temperature for 24 hours to obtain formulation E11.
The E11 formulation is filtered before printing, using an AC filter with a cut-off of around 0.2 μm.

EXAMPLE 2: Obtaining an example of a second E20 ink composition for forming photovoltaic active layer 212.

Depending on whether PC70BM combined with PV2000 or PC70BM combined with PTB7-Th is used, the E201 and E202 ink compositions are obtained, respectively, the compositions of which are detailed in Table 1 below:

TABLE 1

| | | |
|---|---|---|
| Composition | E201 | E202 |

| | | | | |
|---|---|---|---|---|
| PC70BM | 15 | mg | 15 | mg |
| PTB7-Th | 10 | mg | 0 | mg |
| PV2000 | 0 | mg | 10 | mg |
| O-xylene | 1 | mL | 1 | mL |
| Tetralin | 60 | microliters | 60 | microliters |

Ink composition E201 is obtained as follows:
10 mg PTB7-th mixed with 15 mg PC70BM (corresponding to a weight ratio of 1:1.5) in 1 milliliter o-xylene and 60 microliters tetralin.
The mixture is placed under magnetic stirring on a hot plate at 80° C. for 24 hours.
Before printing, the ink is filtered through a 0.45 micrometer AC filter.
The printed layers then undergo thermal annealing on a hot plate at 85° C. for 2 minutes.

The E202 ink composition is obtained as follows:
10 mg PV2000 mixed with 15 mg PC70BM (corresponding to a 1:1.5 mass ratio) in 1 milliliter o-xylene and 60 microliters tetralin.
The mixture is placed under magnetic stirring on a hot plate at 80° C. for 24 hours.
Before inkjet printing, E142 ink is filtered through a 0.45 micrometer AC filter.
After inkjet printing of E201 or E202, photovoltaic active layers are obtained. Once printed, they are subjected to thermal annealing on a hot plate at 85° C. for 2 minutes.

EXAMPLE 3: Obtaining an example of a second E20 ink composition for forming photovoltaic active layer 212.

PC60BM is used as acceptor in combination with PV2000 as donor to obtain the E203 ink composition detailed in Table 1 below:

TABLE 1

| Composition | E203 | |
|---|---|---|
| PC60BM | 22.5 | mg |
| PV2000 | 15 | mg |
| O-xylene | 0.5 | mL |
| Tetralin | 0.5 | mL |

The E203 ink composition is obtained as follows:
15 mg PV2000 mixed with 22.5 mg PC60BM (corresponding to a weight ratio of 1:1.5) in 0.5 ml o-xylene and 0.5 ml tetralin.
The mixture is placed under magnetic stirring on a hot plate at 80° C. for 24 hours.
Before printing, the ink is filtered using an AC filter with a cut-off of around 0.45 micrometers.
After E203 inkjet printing, a photovoltaic active layer is obtained which, once printed, is subjected to thermal annealing on a hot plate at 85° C. for 2 minutes.

EXAMPLE 4: Obtaining examples of third ink composition E30 for making the layer of the upper electrode 213 where this is also the second interfacial layer.

This third ink composition E30 for forming the layer of the upper electrode 213 is obtained as follows:
PEDOT:PSS is filtered through a 0.45 μm filter;
500 μl Triton X-100 (a) is mixed with 200 μl Ethylene Glycol (b), 200 μl Glycerol (c) and 100 μl Ethanolamine (d) in 9 ml deionized water (e);
the resulting mixture is magnetically stirred at 50° C. on a hot plate for 30 minutes, then magnetically stirred at room temperature for 20 minutes;
the initially filtered PEDOT:PSS is mixed with the mixture thus obtained after stirring, in the following proportions: 30 μl of mixture of the 3 additives in deionized water for 1 ml of PEDOT:PSS; the resulting mixture (with PEDOT:PSS) is placed under magnetic stirring on a hot plate at room temperature for at least 1 hour; and
the final E30 solution is degassed for 3 to 5 minutes in an ultrasonic bath before printing.

Depending on whether PEDOT:PSS IJ1005 or PEDOT:PSS ORGACON S315 is used, ink compositions E301 and E302 are obtained respectively, the compositions of which are detailed in the two tables 2 and 3 below:

TABLE 2

| | | Solution X | |
|---|---|---|---|
| Composition | | (a + b + c + d + e) | |
| a-Triton x-100 | a | 500 | μL |
| b-Ethylene Glycol | b | 200 | μL |
| c-Glycerol | c | 200 | μL |
| d-Ethanolamine | d | 100 | μL |
| e-Deionized water | e | 9 | mL |

TABLE 3

| | | |
|---|---|---|
| Composition | E301 | E302 |

| | | | | |
|---|---|---|---|---|
| IJ1005 | 1 | mL | 0 | mL |
| Orgacon S315 | 0 | mL | 1 | mL |
| Solution X | 30 | μL | 30 | μL |

a) + b) + c) + d + e)

EXAMPLE 5: Obtaining an example of a third E30 ink composition for forming layer of the upper electrode 213.

This third E303 ink composition for forming the layer of the upper electrode 213 is obtained as follows:
the PEDOT:PSS solution (IJ1005) initially stored in a refrigerator is filtered with a filter having a cut-off of approximately 0.45 μm;
30 μl of Triton X-100 is mixed with 10 ml of the filtered PEDOT:PSS solution,
the resulting mixture is stirred on a magnetic stirrer at room temperature for 16 hours, and
the final E30 solution is degassed for 3 to 5 minutes in an ultrasonic bath before printing.

EXAMPLE 6: Obtaining examples of photovoltaic modules according to the invention:

A C1 photovoltaic cell in accordance with the invention is produced by the following process:
Supply of a transparent PET or glass support containing the first lower electrode.
A first organic interfacial layer derived from composition E11 of Example 1 is formed on the said first lower electrode. In particular, this layer is formed by digital inkjet printing of ink composition E11, followed by thermal annealing in a convection oven at 145° C. for 3 minutes. The thickness of a first organic interfacial layer 211 printed on the layers of the lower electrode 210 is about 2-5 nm, with Rms roughnesses of less than 2 nm.
A photovoltaic active layer 212 is formed on said first organic interfacial layer 211 by digital inkjet printing with ink composition E203 from example 3, followed by thermal annealing in a convection oven at 145° C. for 3 minutes. The thickness of the printed photovoltaic active layers 212 is approximately 350 nm, with Rms roughnesses of less than 5 nm.
A upper electrode 213 is formed on said photovoltaic active layer 212 by digital inkjet printing with ink composition E303 from example 5, followed by thermal annealing in a convection oven at 145° C. for 3 minutes. The thickness of the printed layers of the upper electrode 213 is approximately 500 nm, with Rms roughnesses of less than 10 nm.

The result of the manufacturing process is a C1A photovoltaic cell comprising, among other things, a first continuous, transparent, free of metal oxide interfacial layer according to embodiments of the invention.

RESULTS AND COMPARISONS: Characterization of the C1 photovoltaic cell obtained in Example 5 and comparison with examples of photovoltaic cells according to the prior art.

The various photovoltaic cells, according to the invention and prior art, have been characterized according to the tests indicated above and the results of these characterizations in Table 4 below.

Two photovoltaic cells (C2A and C2B) according to the prior art have been produced under the same conditions as those used to produce the C1 photovoltaic cell according to the invention.

The first C2A photovoltaic cell differs from the C1 photovoltaic cell by the presence of a lower electrode comprising an indium tin oxide layer and an interfacial layer based on metal oxides, in particular AZO (Aluminium doped ZnO) and the second photovoltaic cell C2B according to the prior art differs from the photovoltaic cell C1 according to the invention by the presence of a lower electrode comprising an indium tin oxide layer and an interfacial layer based on metal oxides, in particular SnO₂ (Tin Dioxide). AZO is marketed by Genesink and SnO₂ is marketed by Avantama.

Photovoltaic cells C2A and C2B according to the prior art have been produced in an inverse structure with the photovoltaic active layer PV2000:PC60BM and PEDOT:PSS as the upper electrode, i.e. with the same active layers and upper electrodes as Example 5 according to the invention.

The C1 photovoltaic cell according to the invention and the C2A, C2B photovoltaic cells according to the prior art were characterized under the same conditions with the same characterization bench described above under the same light intensity.

TABLE 4

| | Light | | | | |
|---|---|---|---|---|---|
| Photovoltaic | intensity in | Voc | Isc | Pmax (in | Filling factor |
| cells | lux | (in V) | (in μA) | μW) | (%) |
| C1 | 1000 | 0.638 | 308 | 138.3 | 70 |
| C2A | 1000 | 0.653 | 266 | 113.8 | 66 |
| C2B | 1000 | 0.633 | 336 | 140.8 | 66 |

The above table shows the photovoltaic parameters (voltage, current, maximum power and fill factor) measured under indoor LED lighting (1000 LUX), it clearly shows that the C1 photovoltaic cell achieves photovoltaic performance very close to, and in some cases better than, that of cells made according to the prior art under the same conditions (same photovoltaic active layer and same electrodes (upper and lower)). The current generated by the cell according to the invention is of the same order of magnitude as that generated by cells made according to the prior art.

The fill factor obtained with the cell produced according to the invention is higher than that obtained with cells produced according to the state of the art under the same conditions, indicating a better interface quality between this interfacial layer and the other layers (lower electrode and active layer).

The photovoltaic performances measured with the C1 photovoltaic cell according to the invention are very encouraging and confirm the good functionality of the first interfacial layer according to the invention in the case of an indoor application (low-light LED-type lighting).

### REFERENCES

Reference 1: Sharaf Sumaiya, Kamran Kardel, and Adel El-Shahat. “Organic Solar Cell by Inkjet Printing—An Overview.” 53, Georgia, USA: Technologies, 2017, Vol. 5.
Reference 2: Peng, X., Yuan, J., Shen, S., Gao, M., Chesman, A. S. R., & Yin, H. (2017). “Perovskite and Organic Solar Cells Fabricated by Inkjet Printing: Progress and Prospects,” Adv. Funct. Mater. 2017, 1703704
Reference 3: European patent application EP2960957 from DRACULA TECHNOLOGIES, filed on Jun. 25, 2015 and published on Dec. 30, 2015.

1. Photovoltaic cell, comprising at least
a transparent support,
a lower electrode covering said support, said lower electrode comprising an upper surface and a lower surface,
a first interfacial layer, said first interfacial layer comprising an upper surface and a lower surface,
a photovoltaic active layer,
a second interfacial layer covering said photovoltaic active layer,
said photovoltaic cell being characterized in that said first interfacial layer is an organic layer having a thickness of between 2 and 5 nm and comprising amine groups at its lower surface in contact with the upper surface of the lower electrode, and
in that said first interfacial layer is continuous, transparent and free from metal oxide.

2. Photovoltaic cell according to claim 1, wherein said first interfacial layer has an Rms roughness of less than 5 nm.

3. Photovoltaic cell according to claim 1, wherein said first interfacial layer comprises nitrogen.

4. Photovoltaic cell according to claim 1, wherein said second interfacial layer comprises a polymer blend of poly(3,4-ethylenedioxythiophene) and sodium poly(styrene sulfonate).

5. Photovoltaic cell according to claim 1, further comprising an upper electrode covering said second interfacial layer.

6. Photovoltaic cell according to claim 1, wherein said second interfacial layer comprising said polymer blend of poly(3,4-ethylenedioxythiophene) and sodium poly(styrene sulfonate) is an upper electrode.

7. Photovoltaic cell according to claim 6, wherein said second interfacial layer is continuous and has a fibrous structure and an average thickness of between 100 nm and 400 nm.

8. Photovoltaic cell according to claim 6, characterized in that it is completely organic.

9. Photovoltaic cell according to claim 1, wherein the first interfacial layer is obtained by digital inkjet printing on the lower electrode of an organic ink composition having a viscosity of between 2 and 50 mPa·s at 20° C. and comprising
between 0.1% and 0.5% by weight of at least one organic polymer or organic molecule relative to the total weight of said ink composition, the organic polymer or organic molecule comprising amine groups and being soluble in polar solvents,
between 2% and 10% by weight of additives relative to the total weight of said ink composition,
between 80% and 90% by weight of one or more polar solvents, relative to the total weight of said ink composition, and
between 1% and 5% by weight of water, based on the total weight of said ink composition.

10. The photovoltaic cell of claim 9, wherein the organic polymer or organic molecule is selected from Poly(9,9-bis(3′-(N,N-dimethyl)-N-ethylammonium-propyl-2,7-fluorene)-alt-2,7-(9,9-dioctylfluorene))dibromide (PFN-Br), polyethyleneimine (PEI), PEIE, Poly [(9,9-bis(3′-(N,N-dimethylamino)propyl)-2,7-fluorene)-alt-2,7-(9,9-dioctylfluorene)](PFN), N,N′-Bis(N,N-dimethylpropan-1-amine oxide)perylene-3,4,9,10-tetracarboxylic diimide (PDI-NO) or N,N′-Bis{3-[3-(Dimethylamino)propylamino]propyl}perylene-3,4,9,10-tetracarboxylic diimide (PDINN).

11. Photovoltaic cell according to claim 9, wherein said one or more solvents are selected from ethanol, isopropanol, hexanole, terpiniol, ethylene glycol, deionized water, phosphate saline buffer solution, butanol, di-ethylene glycol, glycerol.

12. Photovoltaic cell according to claim 9, wherein the organic polymer or organic molecule comprises nitrogen.

13. Photovoltaic module comprising at least two photovoltaic cells according to claim 5, a first photovoltaic cell and a second photovoltaic cell,
the upper electrode of the first photovoltaic cell being in contact with the lower electrode of the second photovoltaic cell.

14. A method of manufacturing a photovoltaic cell, comprising the following steps:
a) providing a support;
b) forming on said support a lower electrode;
c) forming on said lower electrode a first organic interfacial layer comprising a lower surface including amine groups in contact with the lower electrode, the first interfacial layer having a thickness of between 2 and 5 nm, being continuous, transparent, free of metal oxide;
d) forming on said first interfacial layer a photovoltaic active layer;
e) forming on said photovoltaic active layer a second interfacial layer.

15. Method of manufacturing according to claim 14, wherein steps b), c), d) and e) are each carried out by depositing ink compositions by digital inkjet printing, followed by thermal treatment, said ink composition used in step c) comprising a mixture based on organic molecules soluble in polar solvents.
